(19) United States
(12) Patent Application Publication
(10) Pub. No.: US 2006/0181204 A1
(43) Pub. Date: Aug. 17, 2006

(54) Flexible organic light emitting devices

(76) Inventors: Furong Zhu, Singapore (SG); Kian Soo Ong, Singapore (SG); Xiao Tao Hao, Singapore (SG)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/336,879

(22) Filed: Jan. 23, 2006

Related U.S. Application Data
(63) Continuation-in-part of application No. PCT/SG04/00025, filed on Jan. 28, 2004.

(51) Int. Cl. H01L 51/50; H05B 33/00

(52) U.S. Cl. 313/506; 313/511; 313/512; 313/113; 313/114; 428/917; 438/29; 257/98; 257/E51.021

(57) ABSTRACT

A flexible organic light emitting device and a method of fabricating the same. The device comprises a flexible substrate comprising a plastic material; an organic emissive layer formed on the substrate; and a barrier layer for inhibiting oxygen and moisture permeation into the emissive layer.

### FIELD OF THE INVENTION

The present invention generally relates to multicolor organic light emitting devices.

### BACKGROUND OF THE INVENTION

Organic light emitting devices (OLEDs) have recently attracted attention as display devices that can replace liquid crystal displays (LCDs) because OLEDs can produce high visibility by self-luminescence, thus, they do not require back-lighting, which are necessary for LCDs. A typical OLED is constructed by placing an organic light-emitting material between a cathode layer that can inject electrons and an anode layer that can inject holes. When a voltage of proper polarity is applied between the cathode and anode, holes injected from the anode and electrons injected from the cathode combine to release energy as light, thereby producing electroluminescence. Polymeric electroluminescent and phosphorescent materials have been used for OLEDs, which devices are referred to as PLEDs.

One conventional structure of OLED is a bottom-emitting structure, which includes an upper opaque electrode and a transparent lower electrode on a transparent substrate, whereby light can be emitted from the bottom of the structure. The OLED may also have a top-emitting structure, which may be formed on either an opaque substrate or a transparent substrate and has a transparent upper electrode so that light can also emit from the side of the upper electrode.

OLED arrays have been used in multicolor and full color image display devices. An image display includes an array of light emitting pixels. The term “pixel” is employed in the art to designate an area of an image display array that can be stimulated to emit light independently of other areas. The term “multicolor” is used to describe an image display array that is capable of emitting light of a different hue in different areas (“sub-pixels”) of the same pixel. The term “full color” is used to describe multicolor image display arrays that are capable of emitting light in the red (R), green (G), and blue (B) regions of the visible spectrum. In order to achieve full color OLED arrays, it is conventional to deposit three sub-pixels (RGB) containing specific organic emissive materials for each color to form a pixel. Each sub-pixel is defined by an OLED. The available techniques for depositing different color layers (e.g. include ink-jet printing, screen printing, spin-coating, thermal evaporation etc.) produce low yield. Furthermore, the organic emissive materials for producing different colors have different lifespans. Thus, in order to ensure proper color mixtures and tones, complicated thin film transistor (TFT) arrays are required for the display devices in order to compensate for the variations in intensity and hue emitted from the sub-pixels.

An example of a multicolor image display device is disclosed by U.S. Pat. No. 5,703,436. This patent discloses a multicolor OLED that has a vertically stacked layers of double heterostructure devices. The double heterostructure devices are formed of different organic electroluminescent media, each for emitting a distinct color.

U.S. Pat. No. 6,326,224 discloses an OLED having at least one microcavity for purifying a primary color. This patent also discloses the formation of a plurality of microcavities in tandem for successively purifying the light spectrum.

U.S. Patent Application Pub. No. 2003/0052600 discloses a multicolor light emitting display having an array of light emitting elements, each being covered by a sol gel coating. The sol get coating contains a binary optical material to form a diffractive optical element for producing different colors. However, covering different color converting layers on the top of OLED pixels involves substantial fabrication steps, including deposition of different sol gel coatings for different color conversion, light exposure, etching etc.

There remains a need for the development of an effective solution for achieving multicolor or full color OLED displays at a low cost.

### SUMMARY OF THE INVENTION

The present invention provides an organic light emitting display, in which one emissive material is used to generate multicolor images, including full color images. The display of the present invention comprises an OLED structure having a microcavity confined between a top mirror and a bottom mirror. The mirrors may be relatively transparent or opaque depending on whether the OLED structure is a top-emitting OLED or a bottom-emitting OLED. The microcavity comprises an organic medium for providing electroluminescence and a transparent conductive layer. By this arrangement, the color may be tuned by varying the thickness of the transparent conductive layer. In another aspect of the present invention, a multicolor or full color pixelated display is produced by forming an array of OLED structures having microcavities on a substrate. The thickness of the transparent conductive layers in the OLED structures is varied across the substrate surface so as to achieve color tuning.

### BRIEF DESCRIPTION OF THE DRAWINGS

The advantages and novel features of the present invention will become apparent from the following detailed description of exemplary embodiments taken in conjunction with the attached drawings.

FIG. 1 shows a sectional view of a multicolor light-emitting display having a plurality of top-emitting OLED structures according to one embodiment of the present invention.

FIG. 2 shows a sectional view of a multicolor light-emitting display having a plurality of top-emitting OLED structures according to a second embodiment of the present invention.

FIG. 3 shows a sectional view of a multicolor light-emitting display having a plurality of bottom-emitting OLED structures according to a third embodiment of the present invention.

FIG. 4 shows a prototype of a multicolor PLED according to the present invention.

FIG. 5 shows a plot of the EL peak position as a function of the ITO thickness.

### DESCRIPTION OF THE PREFERRED EMBODIMENTS

The multicolor light-emitting display according to the present invention comprises an OLED structure having a microcavity confined between a top mirror and a bottom mirror, as the basic structure. The mirrors may be relatively transparent or opaque depending on whether the OLED structure is a top-emitting OLED or a bottom-emitting OLED. The microcavity comprises an organic mediurn for providing electroluminescence and a transparent conductive (TC) layer. The present invention has various embodiments.

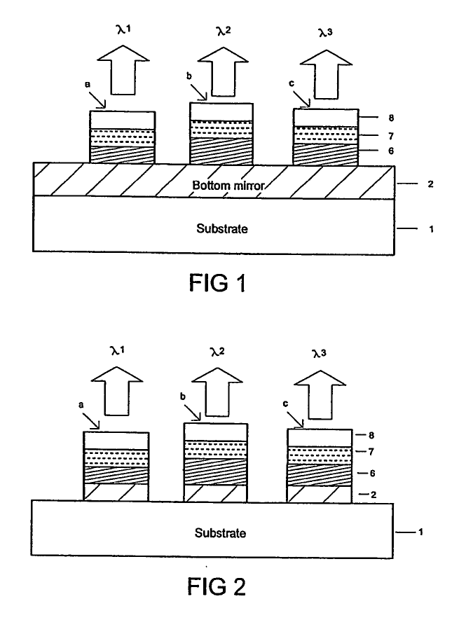

Referring to FIG. 1, the multicolor light-emitting display, according to one embodiment, has a substrate 1 covered with a bottom mirror 2, and an array of top-emitting OLED structures a, b, c formed on the bottom mirror 2. It should be understood by one skilled in the art that only a representative portion of the array is depicted in FIG. 1. Each of the OLED structures comprises a TC layer 6, an organic medium 7 over the TC layer, and a top mirror 8 over the organic medium. The top mirror 8 is transparent or semi-transparent (hereinafter referred to as (relatively transparent). More specifically, the top mirror 8 may be a relatively transparent metal layer or a transparent dielectric mirror, e.g., a distributed Bragg reflector (DBR) mirror. The relatively transparent metallic material includes silver and other high conductive metals. The bottom mirror 2 may be a transparent dielectric mirror (i.e., DBR mirror) or an opaque mirror. When the bottom mirror 2 is a DBR mirror, the DBR mirror may include a quart-wave dielectric stack, e.g., pairs of SiO₂/SiN or SiO₂/TiO₂. An example of an opaque mirror is a highly reflective metal layer. The highly reflective metallic material includes silver, aluminum, chromium, and metal alloys thereof. When the top mirror 8 is a relatively transparent metal layer and the bottom mirror 2 is a highly reflective metal layer, the highly reflective metal layer is thicker than the semi-transparent metal layer. In such an arrangement, the thickness of the highly reflective metal layer may be in the range of 30 nm to 300 nm and the thickness of the relatively transparent metal layer may be in the range of 10 nm to 30 nm. The relatively transparent metal layer may be covered with an index-matching layer in order to enhance the light output. The index-matching layer is made of a transparent organic or inorganic material having a refractive index of greater than 1.2. Examples of the materials for the index-matching layer are tris-(8-hydroxyquinoline) aluminum (Alq3), N,N′-di(naphthalene-1-yl)-N,N′-diphenylbenzidine (NPB), MgF₂, SiO₂, MgO, ITO, ZnO, and TiO₂. The index-matching layer may also serves as a barrier or an encapsulation layer. The index-matching layer may have a thickness of 1 to 500 nm, depending on the reflective index of the material being used.

A thin electron-injecting film may be formed between the relatively transparent top mirror 8 and the organic medium 7 in order to enhance electron injection. The electron-injection film may be formed of a low work function metal or metal alloy. Suitable low work function metals include cesium (Cs), calcium (Ca), lithium (Li), barium (Ba) and magnesium (Mg). The electron-injection film may also be a bi-layer or a composite cathode, e.g. LiF/Al, CsF/Yb, and CsF/Al.

The organic medium 7 may be a single organic layer or a multilayer stack comprising a plurality of organic sub-layers adaptable for light emission. The organic materials for the organic stack include electroluminescent and phosphorescent organic materials that are conventional in the art for light emitting devices. More specifically, the organic stack may be made of electroluminescent and/or phosphorescent polymeric materials conventionally used for PLEDs. In some instances, the organic stack is a bi-layer comprised of a hole transporting layer and a light-emitting layer. Alternatively, the organic stack may be a three-layer stack comprising a hole transporting layer, an electron transporting layer, and an emissive layer between the hole transporting layer and the electron transporting layer. The device having such three-layer organic stack is referred to as a double heterostructure. When a multilayer organic stack with a hole transporting layer is used, the hole transporting layer should be nearest to the TC layer 6. When a multilayer organic stack with an electron transporting layer is used, the electron transporting layer should be closest to the relatively transparent metal layer 8. The total thickness of the organic stack may range from 50 to 1000 nm.

The substrate 1 may be opaque or transparent, and rigid or flexible. Suitable materials for the substrate 1 include plastics, metals, semiconductors, and dielectrics such as glass, quartz, sapphire. Specific examples of substrate 1 are metal-coated plastic sheet, steel foil, metal-coated glass substrate, and silicon substrate. When plastic sheets are used as substrates, a low-temperature deposition process is required for forming the TC layer. The thickness of the substrate 1 depends on the application of the display. A plurality of active elements such as TFTs may be defined on the substrate 1 so as to form an active matrix display. These active elements are operable to selectively activate the organic medium 7 to emit light.

The TC material for the TC layer 6 may be organic or inorganic. The suitable TC materials include, but are not limited to, transparent conductive oxides (TCOs) such as indium tin oxide (ITO), zinc-aluminum-oxide, indium-zinc-oxide, Ga—In—Sn—O, Zn—In—Sn—O, Ga—In—O. Other transparent conductive, organic or inorganic materials are also possible. One important feature of the present invention is that the thickness of the TC layers in OLED structures (a, b, c) is varied for color tuning, whereby a multicolor or full color pixelated display can be produced. The thickness of the TC layer may be adjusted from 10 nm to 500 nm. For example, the thickness of the TC layers in three closely-spaced OLEDs may be adjusted to emit the red, green, and blue regions of the visible spectrum, respectively. FIG. 1 further illustrates that the emission peak wavelengths λ1, λ2, λ3 of the lights emitted through the tops of the OLED structures a, b, c are different from each other due to the variation in the TC layer thickness. As a result, different colors can be produced for the display device by adjusting the thickness of the TC layers.

By the arrangement shown in FIG. 1, a microcavity can be generated between the top mirror 8 and the bottom mirror 2. With this microcavity, high electroluminescence efficiency can be achieved due to the enhanced light extraction. Trapped light in OLEDs, which is caused by internal reflection, is inevitable. In the present invention, by tuning the cavity resonance to wavelengths near the wavelength of the electroluminescence peak, one can spatially redistribute the emission of the display device to redirect fight trapped in the device. As a consequence, the electroluminescence efficiency is enhanced.

In the embodiment of FIG. 1, the top-emitting OLED structures (a, b, c) share a common bottom mirror 2. In an alternative embodiment shown in FIG. 2, the top-emitting OLED structures (a, b, c) are provided with separate bottom mirrors 2.

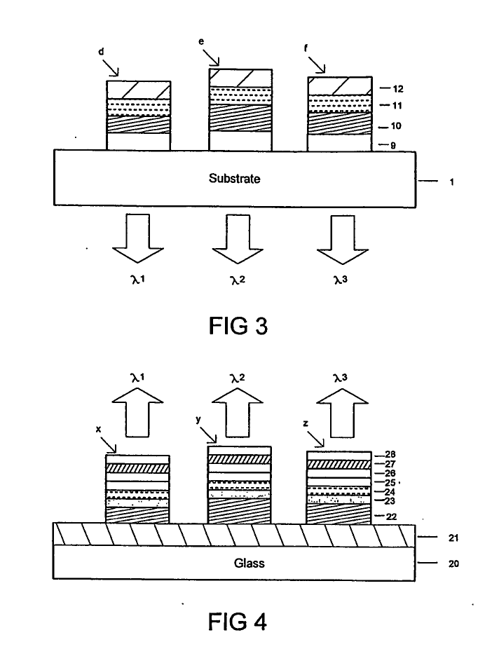

Referring to FIG. 3, the multicolor light-emitting display according to another embodiment comprises a plurality of bottom-emitting OLED structures d, e, f, which are formed on a transparent substrate 1. Each of the bottom-emitting OLED structures d, e, f comprises a semi-transparent or transparent (“relatively transparent”) bottom mirror 9 as the lowest layer, a TC layer 10 over the bottom mirror 9, an organic medium 1 1 over the TC layer 10, and an opaque top mirror 12 over the organic medium 11. The substrate 1 may be rigid or flexible. The suitable materials for the substrate 1 include glass and plastic. The bottom mirror 9 may be a transparent dielectric mirror or a relatively transparent metal layer. The relatively transparent metal includes silver or other highly reflective conductive metals and alloys thereof. The opaque top mirror 12 may be made of a highly reflective metal. When the top mirror 12 is made of highly reflective metal and the bottom mirror 9 is made of a relatively transparent metal, the highly reflective metal layer is thicker than the relatively transparent metal layer. The suitable thickness for the highly reflective metal layer and the relatively transparent metal layer is as described for FIG. 1. The suitable materials and thickness for the organic medium 11, and the TC layer 10 are similar to those described for FIG. 1. An electron-injection layer may be formed between the organic medium 11 and the top mirror 12. The suitable materials and thickness for the electron-injection layer are also similar to those described for FIG. 1. Because the TC layers of the OLED structures d, e, f have varying thickness, the emission wavelengths λ1, λ2, λ3 of the lights emitted through the bottoms of the OLED structures d, e, f are different from each other.

As a result of the present invention, one emissive material is used to generate multicolor images, including full color images. Full color light-emitting devices can be fabricated by adjusting the TC thickness in an array of OLEDs so as to produce the required RGB pixels.

### AN EXAMPLE OF THE PRESENT INVENTION

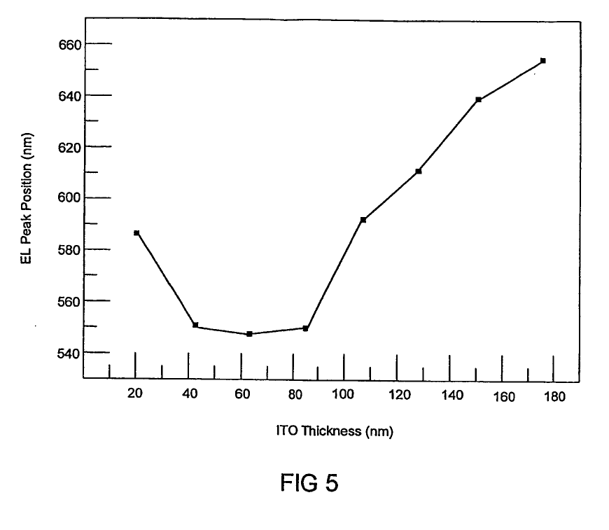

FIG. 4 shows a prototype of a multicolor PLED according to the present invention. A 0.7 mm thick glass substrate 20 is covered with a 300 nm thick bottom mirror 21 made of Ag/Cr alloy. An array of PLEDs are formed on the bottom mirror 21, only three PLEDs (x, y, z) are being shown in FIG. 4. Each PLED is composed of, in order from bottom to top, an ITO layer 22 of varying thickness (20-180 nm), a 30 nm thick poly(styrene sulfonate)-doped poly(3,4-ethylene dioxythiophene (PEDOT) layer 23, an 80 nm thick phenyl-substituted poly(p-phenylenevinylene) (Ph-PPV) layer 24, a 0.6 nm thick LiF layer 25, a 1.5 nm thick Ca layer 26, a 15 nm thick top mirror 27 made of Ag, and a 52 nm thick tris-(8-hydroxyquinoline) aluminum (Alq3) index-matching layer 28. The thickness of the ITO layers in the PLEDs is adjusted between the range of 20 to 180 nm so as to produce a multicolor display. FIG. 5 illustrates the correlation between the thickness of the ITO layer and the electroluminescence (EL) peak position. The EL peak shows a blue shift from 586 nm to 547 nm when the thickness of the ITO increases from 20 nm to 65 nm. There is a red shift in EL spectra from 547 nm to 655 nm when the ITO layer thickness increases from 65 nm to 175 nm.

While the present invention has been described with respect to a limited number of embodiments, those skilled in the art will appreciate numerous modifications and variations therefrom. It is intended that all such modifications and variations are covered by the spirit and scope of the appended claims.

What is claimed is:

1. A light-emitting display comprising:
a substrate; and
at least one organic light-emitting diode (OLED) structure formed over the substrate, said at least one OLED structure comprising a bottom mirror, a top mirror, and a microcavity formed between the bottom mirror and the top mirror, wherein the microcavity comprises a transparent conductive layer and an organic medium for providing electroluminescence.

2. The light-emitting display of claim 1, wherein the top mirror is transparent or semi-transparent.

3. The light-emitting display of claim 2, wherein the top mirror is a transparent dielectric mirror.

4. The light-emitting display of claim 2, wherein the top mirror comprises a transparent or semi-transparent metal.

5. The light-emitting display of claim 4, wherein the transparent or semi-transparent metal is silver.

6. The light-emitting display of claim 2, wherein the bottom mirror is a transparent dielectric mirror.

7. The light-emitting display of claim 6, wherein the transparent dielectric mirror comprises quarter-wave layers of SiO2/TiO₂ or SiO₂/SiN.

8. The light-emitting display of claim 3, wherein the dielectric mirror is a distributed Bragg reflector mirror.

9. The light-emitting display of claim 6, wherein the dielectric mirror is a distributed Bragg reflector mirror.

10. The light-emitting display of claim 2, wherein the bottom mirror is an opaque mirror.

11. The light-emitting display of claim 9, wherein the opaque mirror comprises a highly reflective metal layer.

12. The light-emitting display of claim 11, wherein the highly reflective metal layer comprises a metal selected from the group consisting of silver, aluminum, chromium and alloys thereof.

13. The light-emitting display of claim 1, wherein the top mirror is opaque.

14. The light-emitting display of claim 13, wherein the top mirror comprises a highly reflective metal layer.

15. The light-emitting display of claim 13, wherein the bottom mirror is a transparent dielectric mirror.

16. The light-emitting display of claim 15, wherein the transparent dielectric mirror comprises quarter-wave layers of SiO2/TiO₂ or SiO₂/SiN.

17. The light-emitting display of claim 15, wherein the transparent dielectric mirror is a distributed Bragg reflector mirror.

18. The light-emitting display of claim 13, wherein the bottom mirror comprises a transparent or semi-transparent metal.

19. The light-emitting display of claim 18, wherein the semi-transparent or transparent metal layer comprises silver.

20. The light-emitting display of claim 2, wherein the substrate is transparent.

21. The light-emitting display of claim 2, wherein the substrate is opaque.

22. The light-emitting display of claim 1, wherein the substrate is rigid.

23. The light-emitting display of claim 1, wherein the substrate is flexible.

24. The light-emitting display of claim 13, wherein the substrate is transparent.

25. The light-emitting display of claim 1, wherein the substrate is selected from the group consisting of a metal-coated plastic sheet, a steel foil, a metal-coated glass substrate, and a silicon substrate.

26. The light-emitting display of claim 1, wherein the bottom mirror comprises a highly reflective metal layer and the top mirror comprises a semi-transparent or transparent metal layer, the highly reflective metal layer being thicker than the semi-transparent or transparent metal layer.

27. The light-emitting display of claim 1, wherein the top mirror comprises a highly reflective metal layer and the bottom mirror comprises a semi-transparent or transparent metal layer, the highly reflective metal layer being thicker than the semi-transparent or transparent metal layer.

28. The light-emitting display of claim 1, wherein the transparent conductive layer comprises a transparent conductive organic or inorganic material.

29. The light-emitting display of claim 1, wherein the transparent conductive layer comprises a transparent conductive oxide (TCO) material selected from the group consisting of indium-tin-oxide (ITO), zinc-aluminum-oxide, indium-zinc-oxide, Ga—In—Sn—O, SnO₂, Zn—In—Sn—O, and Ga—In—O.

30. The light-emitting display of claim 2 further comprising an electron-injection layer positioned between the organic medium and the top mirror in order to enhance electron injection.

31. The light-emitting display of claim 30, wherein the electron-injection layer comprises a low work function metal or a low work function metal alloy.

32. The light-emitting display of claim 31, wherein the low work function metal is selected from the group consisting of Cs, Ca, Li, Ba and Mg.

33. The light-emitting display of claim 30, wherein the electron-injection layer comprises a bi-layer structure or a composite cathode.

34. The light-emitting display of claim 33, wherein the electron-injection layer is a bi-layer structure selected from the group consisting of LiF/Al, CsFNb, and CsF/Al.

35. The light-emitting display of claim 2 further comprising an index-matching layer formed over the top mirror, the index-matching layer having a refractive index effective for enhancing light output.

36. The light-emitting display of claim 35, wherein the index-matching layer comprises an organic or inorganic material having a refractive index greater than 1.2.

37. The light-emitting display of claim 35, wherein the index-matching layer is made of tris-(8-hydroxyquinoline) aluminum (Alq3) or N,N′-di(naphthalene-1-yl)-N,N′-diphenylbenzidine, MgF₂, SiO₂, MgO, ITO, ZnO, and TiO₂.

38. The light-emitting display of claim 4 further comprising an index-matching layer formed over the top mirror, the index-matching layer having a refractive index effective for enhancing light output.

39. The light-emitting display of claim 38, wherein the index-matching layer comprises an organic or inorganic material having a refractive index greater than 1.2.

40. The light-emitting display of claim 38, wherein the index-matching layer is made of tris-(8-hydroxyquinoline) aluminum (Alq3) or N,N′-di(naphthalene-1-yl)-N,N′-diphenylbenzidine, MgF₂, SiO₂, MgO, ITO, ZnO, and TiO₂.

41. The light-emitting display of claim 1, wherein an array of OLED structures are formed over the substrate and the thickness of the TC layers in the corresponding OLED structures is varied to achieve color tuning, thereby producing a multicolor light-emitting display.
